(19) United States
(12) Patent Application Publication
(10) Pub. No.: US 2014/0168909 A1
(43) Pub. Date: Jun. 19, 2014

(54) GAPPED ATTACHMENT STRUCTURES

(71) Applicants: Tieyu Zheng, Chandler, AZ (US); Jin A. Zhao, San Jose, CA (US); Ru Han, Chandler, AZ (US); Min Pei, Chandler, AZ (US)

(72) Inventors: Tieyu Zheng, Chandler, AZ (US); Jin A. Zhao, San Jose, CA (US); Ru Han, Chandler, AZ (US); Min Pei, Chandler, AZ (US)

(21) Appl. No.: 13/719,506

(22) Filed: Dec. 19, 2012

(51) Int. Cl. H05K 1/18; H05K 1/03

(52) U.S. Cl. CPC H05K 1/181; H05K 1/03
USPC 361/743; 174/258; 361/728

(57) ABSTRACT

Attachment structures for electrically coupling a microelectronic package to a microelectronic board/interposer including joint pads formed on the microelectronic board/interposer which provide a gap between respective openings in a solder resist layer of the microelectronic substrate and each of the joint pads. Such attachment structures may reduce or substantially eliminate contact between a solder interconnect and a solder resist layer of the microelectronic board/interposer, which may, in turn, reduce or substantially eliminate the potential of crack initiation and propagation at contact areas between the solder interconnect and a solder resist layer of the microelectronic board/interposer due to stresses induced by a mismatch of thermal expansion between the microelectronic package and the microelectronic board/interposer during thermal cycling. Further, the connection area between the pad and outside circuitry may be maximized, so that the impact to electrical performance due to the pad design may be minimized.

### BACKGROUND

Embodiments of the present description generally relate to the field of microelectronic assemblies and, more particularly, to the attachment of microelectronic devices to microelectronic board/interposers using joint pads which are designed to form a gap between each joint pad and a solder resist material surrounding each joint pad to reduce or substantially eliminate the potential of crack initiation and propagation while minimizing the impacts to electrical performance.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of a microelectronic device positioned on a microelectronic substrate prior to attachment, as known in the art.

FIG. 2 is a side cross-sectional view of a microelectronic device mounted on a microelectronic substrate, as known in the art.

FIG. 3 is a side cross-sectional view of a single package-to-substrate interconnect, as known in the art.

FIG. 4 is top plan view of along line 4-4 of FIG. 3 without the interconnect illustrated, as known in the art.

FIG. 5 is a side cross-sectional view attachment structure, as known in the art.

FIG. 6 is a top plan view of a long line 6-6 of FIG. 5, as known in the art.

FIG. 7 is a top plan view of an embodiment of an attachment structure, as known in the art.

FIG. 8 is a top plan view of another embodiment of an attachment structure, as known in the art.

FIG. 9 is a top plan view of an attachment structure, according to an embodiment of the present description.

FIG. 10 is a top plan view of an attachment structure, according to another embodiment of the present description.

FIG. 11 is a top plan view of the microelectronic substrate, according to an embodiment of the present description.

FIG. 12 is a top plan view of the microelectronic substrate, according to another embodiment of the present description.

FIG. 13 is a side cross-sectional view of a single package-to-substrate interconnect, according to an embodiment of the present description.

FIG. 14 is a top plan view of an attachment structure, according to still another embodiment of the present description.

FIG. 15 is an electronic device/system, according to another embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of fabricating attachment structures for electrically coupling a microelectronic package to a microelectronic board/interposer. These attachment structures may include joint pads formed on the microelectronic board/interposer which provide a gap between respective openings in a solder resist layer of the microelectronic board/interposer and each of the joint pads. The gap may be positioned substantially opposite a center point of a microelectronic device within the microelectronic package, and may be positioned such that a midpoint vector of the gap may be substantially perpendicular to a nearest edge of a microelectronic device within the microelectronic package relative to each joint pad. Such a configuration may reduce or substantially eliminate contact between a solder interconnect and a solder resist layer of the microelectronic board/interposer, which, in turn, may reduce or substantially eliminate the potential of crack initiation and propagation at contact areas between the solder interconnect and a solder resist layer of the microelectronic board/interposer. This crack initiation and propagation may result from stresses induced by a mismatch of thermal expansion between the microelectronic package and the microelectronic board/interposer during thermal cycling.

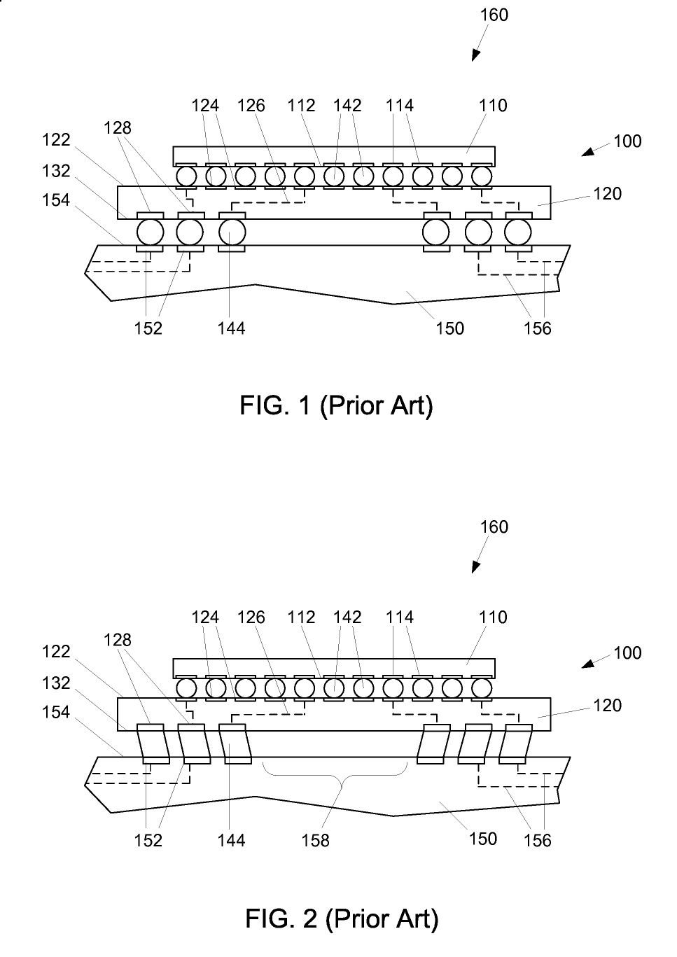

In the production of microelectronic systems, microelectronic packages are generally mounted on microelectronic board/interposers, which provide electrical communication routes between the microelectronic packages and external components. As shown in FIG. 1, a microelectronic package 100 may comprise a microelectronic device 110, such as a microprocessor, a chipset, a graphics device, a wireless device, a memory device, an application specific integrated circuit, or the like, attached to a first surface 122 of a microelectronic substrate 120 through a plurality of interconnects 142, such as reflowable solder bumps or balls, in a configuration generally known as a flip-chip or controlled collapse chip connection (“C4”) configuration. The device-to-substrate interconnects 142 may extend from joint pads 114 on an active surface 112 of the microelectronic device 110 and joint pads 124 on the microelectronic substrate first surface 122. The microelectronic device joint pads 114 may be in electrical communication with integrated circuitry (not shown) within the microelectronic device 110. The microelectronic substrate 120 may include at least one conductive route 126 extending therethrough from at least one microelectronic substrate first surface joint pad 124 and at least one microelectronic package joint pad 128 on or proximate a second surface 132 of the microelectronic substrate 120. The microelectronic substrate 120 may reroute a fine pitch (center-to-center distance between the microelectronic device joint pads 114) of the microelectronic device joint pads 114 to a relatively wider pitch of the microelectronic package joint pads 128.

The microelectronic package 100 may be attached to a microelectronic board/interposer 150, such as printed circuit board, a motherboard, and the like, through a plurality of interconnects 144, such as reflowable solder bumps or balls, to form a microelectronic system 160. The package-to-board/interposer interconnects 144 may extend between the microelectronic package joint pads 128 and substantially mirror-image joint pads 152 on an attachment surface 154 of the microelectronic board/interposer 150. The microelectronic board/interposer joint pads 152 may be in electrical communication with conductive routes (shown as dashed lines 156) within the microelectronic board/interposer 150. The microelectronic board/interposer conductive routes 156 may provide electrical communication routes to external components (not shown).

Both the microelectronic substrate 120 and the microelectronic board/interposer 150 may be primarily composed of any appropriate material, including, but not limited to, bismaleimine triazine resin, fire retardant grade 4 material, polyimide materials, glass reinforced epoxy matrix material, and the like, as well as laminates or multiple layers thereof. The microelectronic substrate conductive routes 126 and the microelectronic board/interposer conductive routes 156 may be composed of any conductive material, including but not limited to metals, such as copper and aluminum, and alloys thereof. As will be understood to those skilled in the art, microelectronic substrate conductive routes 126 and the microelectronic board/interposer conductive routes 156 may be formed as a plurality of conductive traces (not shown) formed on layers of dielectric material (constituting the layers of the microelectronic board/interposer material), which are connected by conductive vias (not shown).

The package-to-board/interposer interconnects 144 can be made of any appropriate material, including, but not limited to, solders materials. The solder materials may be any appropriate material, including but not limited to, lead/tin alloys, such as 63% tin/37% lead solder, and high tin content alloys (e.g. 90% or more tin), such as tin/bismuth, eutectic tin/silver, ternary tin/silver/copper, eutectic tin/copper, and similar alloys. When the microelectronic device 110 is attached to the microelectronic board/interposer 150 with package-to-board/interposer interconnects 144 made of solder, the solder is reflowed, either by heat, pressure, and/or sonic energy to secure the solder between the microelectronic package joint pads 128 and the microelectronic board/interposer joint pads 152.

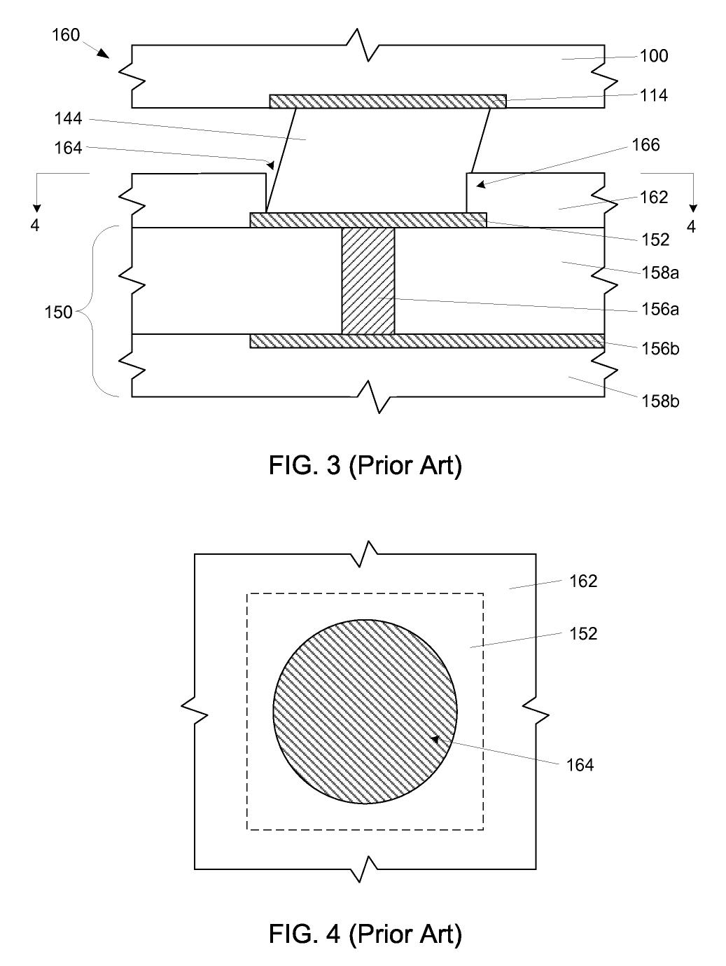

Generally, the microelectronic board/interposer 150 has a higher coefficient of expansion than the coefficient of expansion of the microelectronic package 100 due to the predominant material(s) of the microelectronic package 100 (such as silicon of the microelectronic device 110) and the predominant material(s) of the microelectronic board/interposer 150 (such as organic materials). When the microelectronic package 100 is attached to the microelectronic board/interposer 150, the package-to-board/interposer interconnects 144 are heated to a reflow temperature (usually between about 180 and 260 degrees Celsius). As the microelectronic package 100 and microelectronic board/interposer 150 cool from the reflow temperature, the microelectronic board/interposer 150 tends to shrink more than the microelectronic package 100, which may deform or skew the package-to-board/interposer interconnects 144 toward a center area 158 of microelectronic board/interposer 150 proximate the microelectronic board/interposer joint pads 152, as shown in FIGS. 2 and 3. It is understood that the actual shape of the package-to-board/interposer interconnects 144 will not necessary be the precise shape that is illustrated.

As shown in FIG. 3, this skewing may result in the package-to-board/interposer interconnect 144 contacting a solder resist material layer 162, which is disposed on the microelectronic board/interposer 150. The solder resist material layer 162 may substantially surround each microelectronic board/interposer joint pads 152 to define an opening 164 therethrough and may be utilized to contain a solder material on the microelectronic board/interposer joint pads 152 during the formation of the package-to-board/interposer interconnects 144, as will be understood to those skilled in the art. The solder resist material layer 162 may include, but is not limited to, epoxy resin, epoxy-acrylate resin, and liquid photoimageable materials.

During normal operation of an electronic device, the temperature of components, such as the microelectronic package 100 thermally cycles (e.g. heats and cools). Due to the inherent differences in the coefficients of the thermal expansion of the components, cracks may initiate and grow at the contacting area(s) 166 between the package-to-board/interposer interconnect 144 and the solder resist material layer 162, which may degrade a fatigue capability of microelectronic package 100, as will be understood to those skilled in the art. This may ultimately result in the failure of the microelectronic system 160.

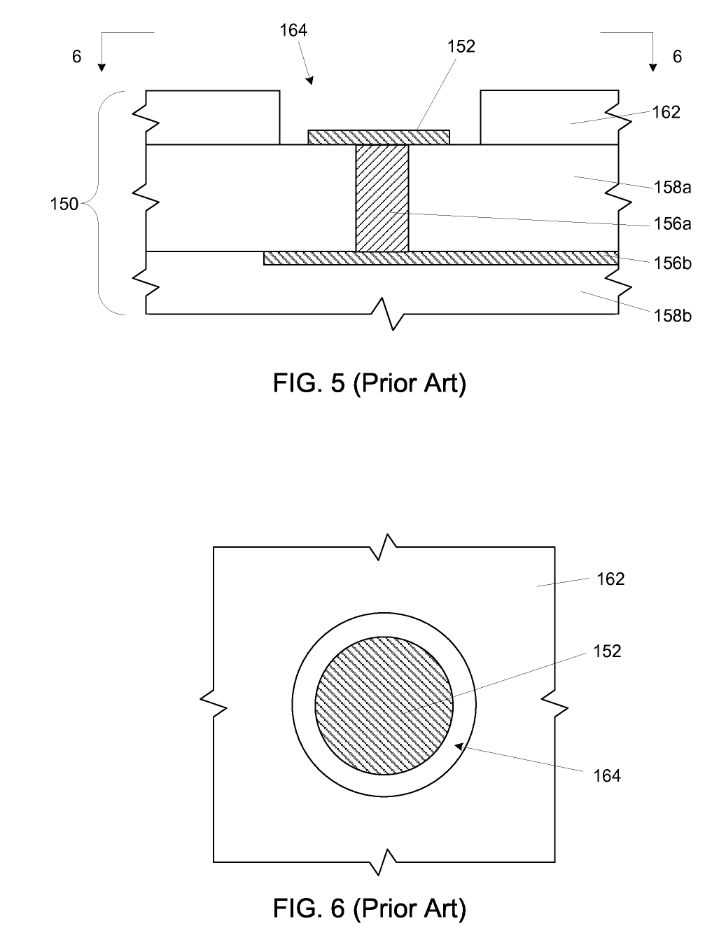

As further shown in FIGS. 3 and 4, the microelectronic board/interposer joint pad 152 may formed such that it completely fills the solder resist material layer opening 164 (known as “solder mask defined (SMD) pads”, in general, the microelectronic board/interposer joint pad 152 is large than the solder resist material layer opening 164). Although such solder mask defined pads are preferred for some electrical design consideration, such as power and ground, as provide the largest area for current to pass through from the joint pad inside area to outside circuitry (not shown), solder mask defined pads may be a worst case scenario with regard to the potential of crack initiation and propagation, because the package-to-board/interposer interconnect 144 may have substantially the greatest contact with the solder resist material layer 162. Alternately, as shown in FIGS. 5 and 6, the microelectronic board/interposer joint pad 152 may be defined to be smaller than the solder resist material layer opening 164 (known as “metal defined (MD) pads”). Although metal defined pads reduce or substantially eliminate the potential of crack initiation and propagation, they disconnect the in-plane routing between the joint pad and an outside area or circuitry (not shown), and force the use of vias and traces for routing purposes, which makes the routing complicate and can degrade electrical behavior, as will be understood to those skilled in the art. For example purposes, microelectronic board/interposer conductive routes 156 are illustrated as a conductive trace via 156a extending through a first dielectric layer 158a, which is electrically coupled to a conductive trace 156b disposed between the first dielectric layer 158a and a second dielectric layer 158b.

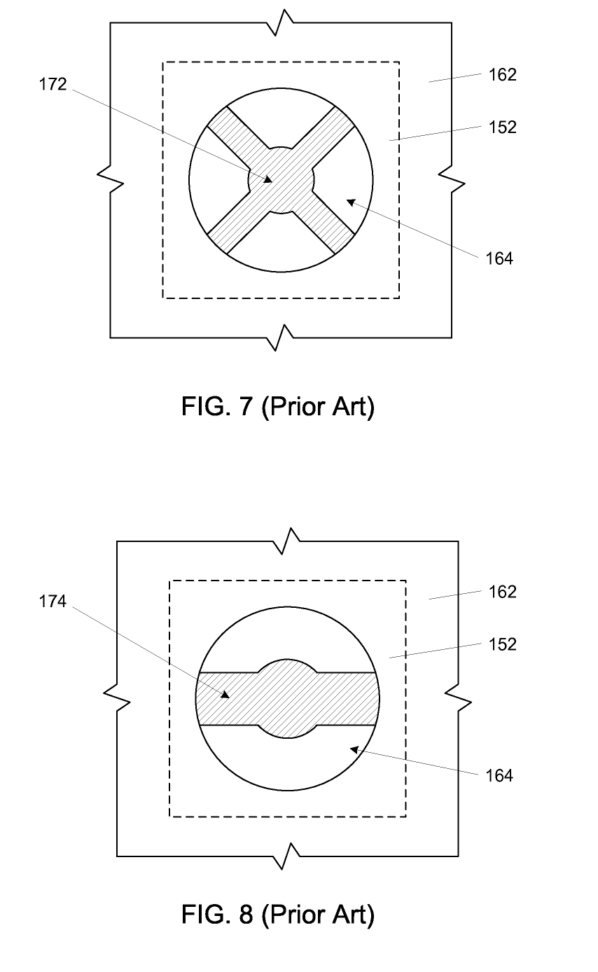

In order to reduce crack initiation and propagation, specifically designed joint pads have been used to minimize contact between the package-to-board/interposer interconnects 144 and the solder resist material layer 162. For example shapes such as “poked pads” 172, as shown in FIG. 7, which is essentially an “X” or “+” shape, or “fat trace pads” 174, as shown in FIG. 8, which is essentially a wide stripe, have been used. However, the poked pads 172 and the fat trace pads 174 may still cause significant contact between package-to-board/interposer interconnect 144 and solder resist material layer 162, which may result in component failure, as previously discussed. As a result, it may be necessary to introduce scarified joints which do not perform any electrical function and are therefore allowed to fail to protect functional joints, as will be understood those skilled in the art. Alternatively, redundant joints are introduced for the same function to assure electrical function in case some of the joints fail due to the thermo-mechanical fatigue stress, as will also be understood those skilled in the art. However, the use of scarified or redundant joints may result in an increase the overall number of package-to-board/interposer interconnects, which may increase the size of the microelectronic system 160 and the cost thereof. Furthermore, the poked pads 172 or the fat trace pads 174 may have limited (in-plane) connection area with outside circuitry (not shown), which may impact power delivery or high speed signal transfer capabilities.

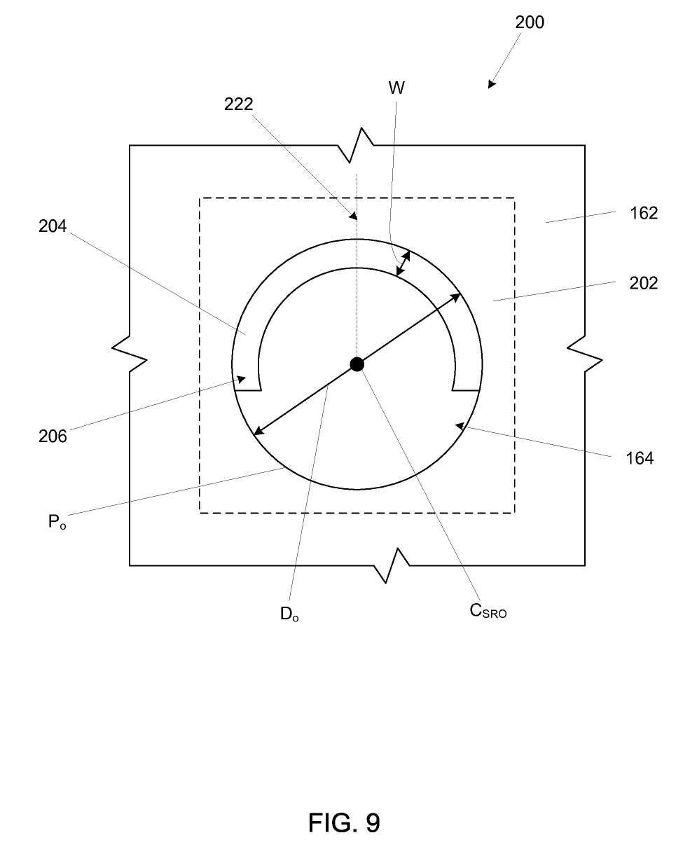

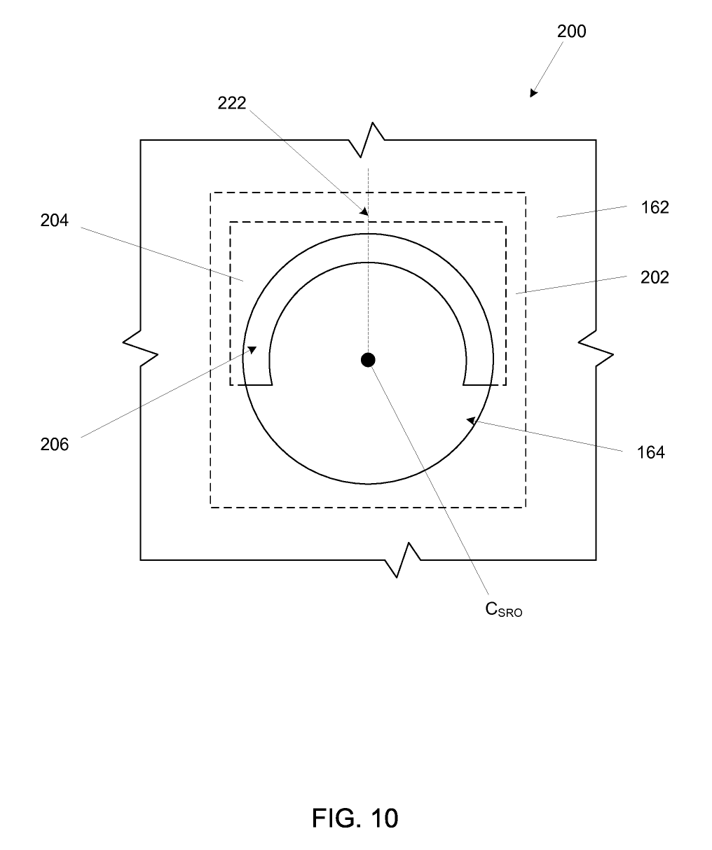

Embodiments of the present description may include an attachment structure which is specifically designed in consideration of the actual package-to-board/interposer interconnect 144 skewing or deformation due to the coefficient of thermal expansion mismatch between the microelectronic package 100 and the microelectronic board/interposer 150, as previously discussed. As illustrated in FIG. 9, one embodiment of an attachment structure 200 may include at least one joint pad 202 on the microelectronic board/interposer 150, wherein the attachment structure joint pad 202 includes an opening 204 extending therethrough and the solder resist material layer 162 disposed on the microelectronic board/interposer 150, wherein the solder resist material layer opening 164 exposes at least a portion of the attachment structure joint pad 202 and wherein the joint pad opening 204 and the solder resist material layer opening 164 define a gap 206 between the attachment structure joint pad 202 and the solder resist material layer 162. Although the joint pad opening 204 is illustrated as the same shape as the attachment structure gap 206, the present description is not so limited. For example, as illustrated in FIG. 10, the joint pad opening 204 may be larger than the desired attachment structure gap 206 size and/or shape, such that a portion of the joint pad opening 204 and a portion of the solder resist material layer opening 164 define the desired attachment structure gap 206 size and/or shape.

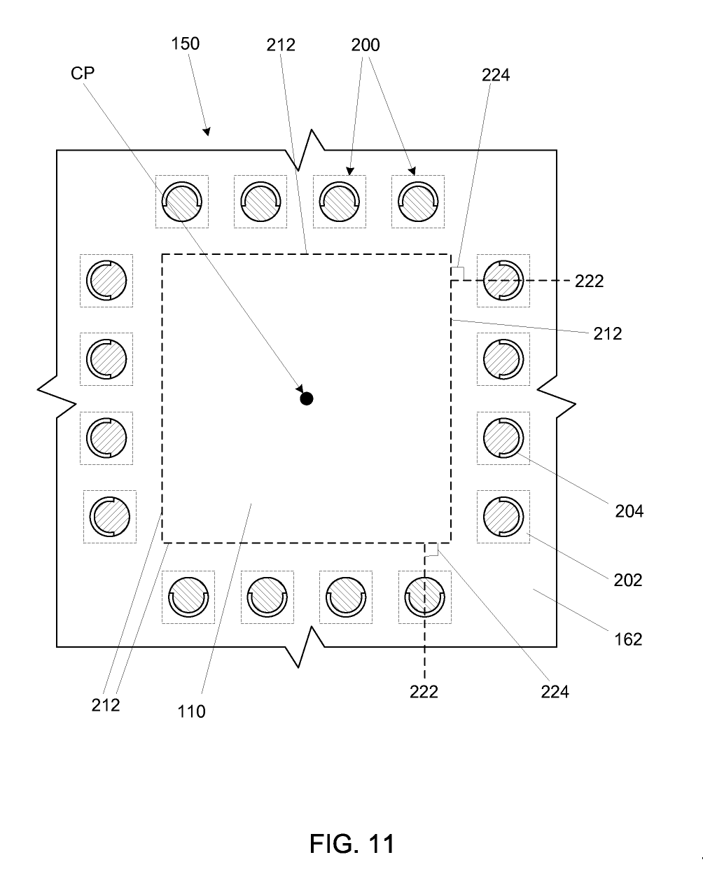

In one embodiment, as shown in FIG. 11, the attachment structure gaps 206 may be positioned substantially opposite a center point CP of the microelectronic device 110 (defined by dashed lines) within the microelectronic package (not shown) and may be oriented such that a midpoint vector 222 of the attachment structure gap 206 is substantially perpendicular 224 to a nearest edge 212 of the microelectronic device 110 relative to each joint pad 202. As illustrated, the attachment structure gap 206 may be oriented substantially opposite the microelectronic device nearest edge 212/The midpoint vector 222 may be defined to include a vector initiating from a center point C_{SRO} of the solder resist layer opening 164 and extending through the gap 206 at a position which substantially bifurcates the attachment structure gap 206.

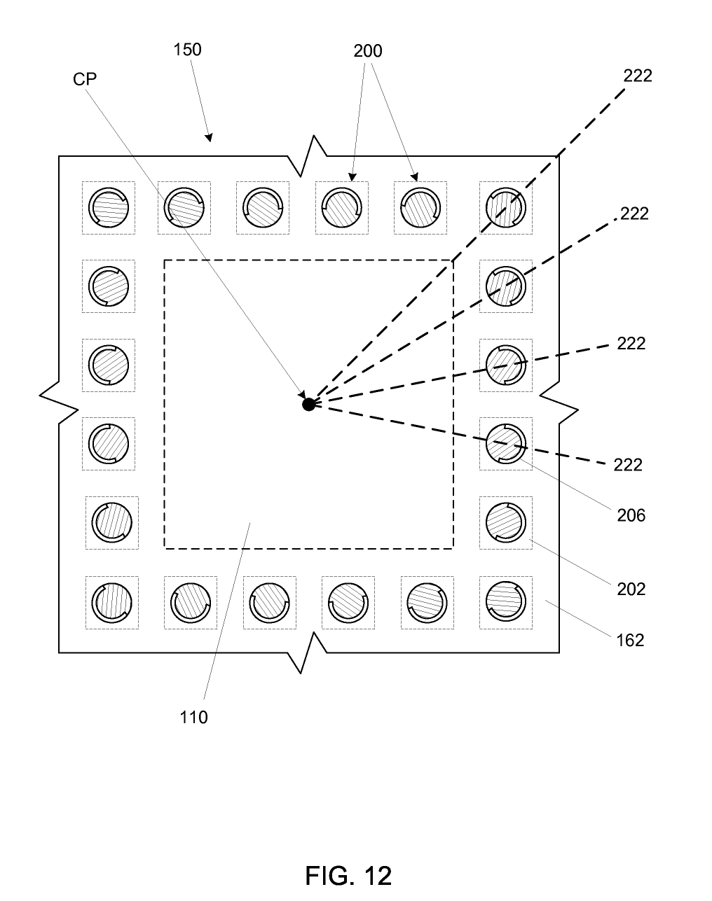

In another embodiment, as shown in FIG. 12, the attachment structure gaps 206 may be positioned substantially opposite a center point CP of the microelectronic device 110 (shown in dashed lines) within the microelectronic package (not shown) and may be positioned such that a midpoint vector 222 of the attachment structure gap 204 may be substantially oriented toward the microelectronic device center point CP. Thus, the midpoint vectors 222 may have a radial pattern relative to the microelectronic device center point CP.

Referring again to FIG. 9, in one embodiment of the present description, the attachment structure gap 206 may be adjacent to a periphery Pₒ of the solder resist material layer opening 164 and extend between about 50% and 75% of solder resist material layer opening periphery Pₒ. In another embodiment of the present description, an average width W of the attachment structure gap 206 may be between about 5% and 20% of an average diameter Dₒ of the solder resist material layer opening 164.

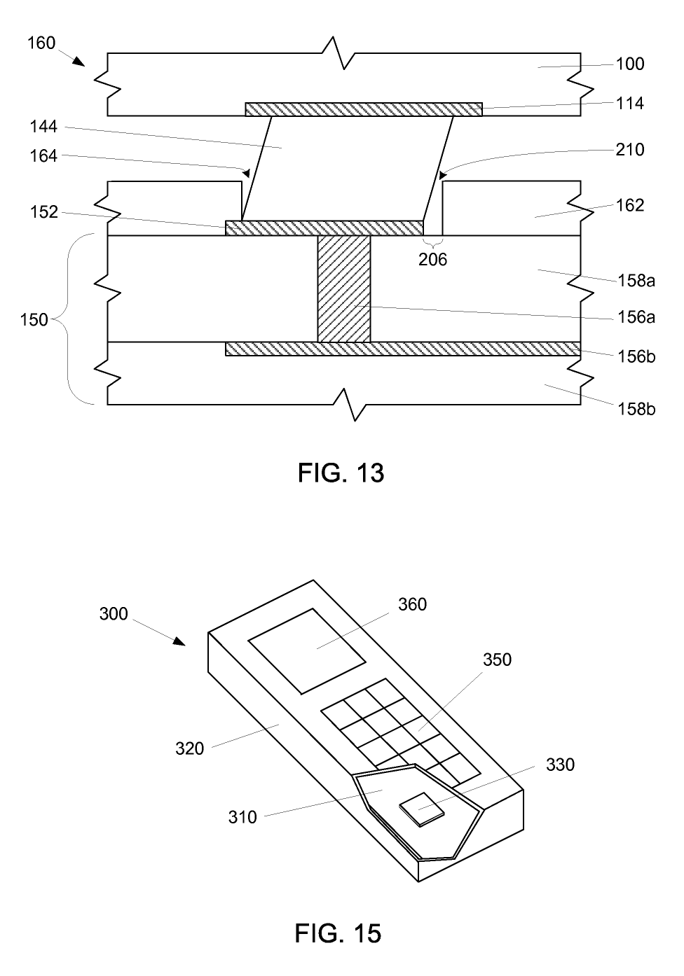

As shown in FIG. 13, the attachment structure gap 206 results in a gap 210 between package-to-board/interposer interconnect 144 and the solder resist material layer 162. Thus, the package-to-board/interposer interconnect 144 skewing is less likely to result in contact between the package-to-board/interposer interconnect 144 and the solder resist material layer 162, thereby reducing or substantially eliminating the chance of crack initiation and propagate during thermal cycling. Meanwhile, the embodiments of the present description maintains larger connection area between the between and an outside area or circuitry compared with poked or fat-trace pads, thereby facilitating comparatively better electrical behavior. As will be understood to those skilled in the art, embodiments of the present invention may result in reduction the number or necessity for scarified or redundant interconnect joints, which, in turn, may minimize the microelectronic package 100 size and/or cost without sacrificing electrical performance or reliability.

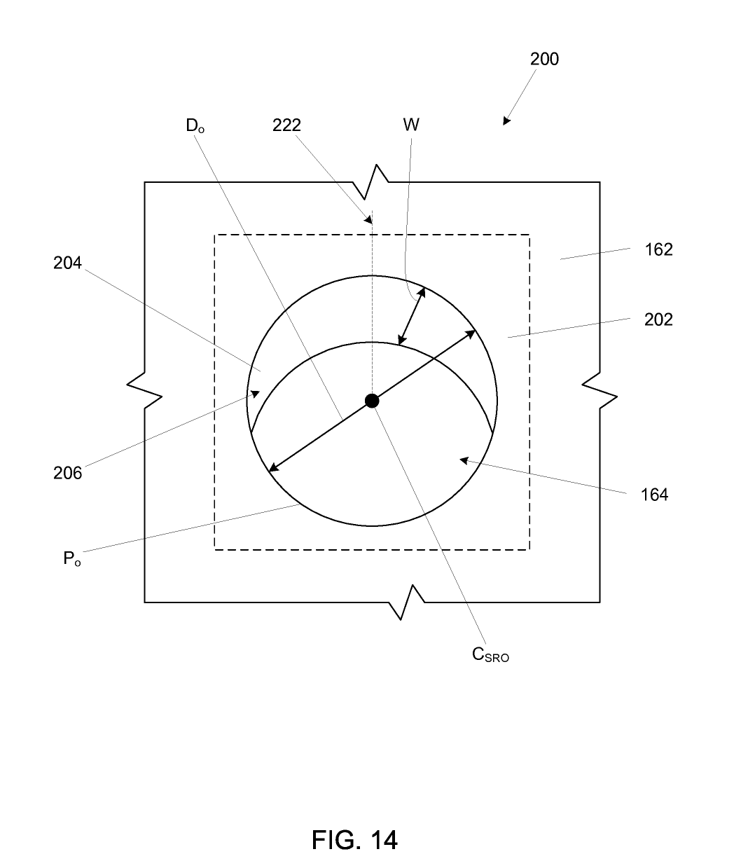

It is understood that embodiments of the present description are not limited the specific shape illustrated in FIGS. 9-13, as the attachment structure gap 206 may have any appropriate size and/or shape. For example, the attachment structure width W may vary over the sweep of the attachment structure gap 206. One embodiment of the varying gap width W is illustrated in FIG. 14, wherein the attachment structure gap 206 may be substantially crescent-shaped.

FIG. 15 illustrates an embodiment of an electronic system/device 300, such as a portable computer, a desktop computer, a mobile telephone, a digital camera, a digital music player, a web tablet/pad device, a personal digital assistant, a pager, an instant messaging device, or other devices. The electronic system/device 300 may be adapted to transmit and/or receive information wirelessly, such as through a wireless local area network (WLAN) system, a wireless personal area network (WPAN) system, and/or a cellular network. The electronic system/device 300 may include a microelectronic motherboard or substrate 310 disposed within a device housing 320. The microelectronic motherboard/substrate 310 may have various electronic components electrically coupled thereto including a microelectronic package 330 attached to the microelectronic motherboard/substrate 310, wherein the microelectronic motherboard/substrate 330 has at least one of gapped attachment structure (not shown), as previously described. The microelectronic motherboard/substrate 310 may be attached to various peripheral devices including an input device 350, such as keypad, and a display device 360, such an LCD display. It is understood that the display device 360 may also function as the input device, if the display device 360 is touch sensitive.

It is understood that the subject matter of the present description is not necessarily limited to specific applications illustrated in FIGS. 1-15. The subject matter may be applied to other microelectronic device and assembly applications, as will be understood to those skilled in the art.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An microelectronic structure, comprising:
a microelectronic board/interposer; and
at least one attachment structure including:
a joint pad disposed on the microelectronic board/interposer having an opening defined therethrough; and
a solder resist material layer disposed on the microelectronic board/interposer having an opening defined therethrough that exposes at least a portion of the joint pad;
wherein the joint pad opening and the solder resist material layer opening define a gap between the joint pad and the solder resist material layer extending adjacent a periphery of solder resist material layer opening and along about 50% to 75% of the solder resist material layer opening periphery.

2. The microelectronic structure of claim 1, wherein an average width of the attachment structure gap is between about 5% to 20% of an average diameter of the solder resist material layer opening.

3. An microelectronic structure, comprising:
a microelectronic board/interposer;
at least one attachment structure including:
a joint pad disposed on the microelectronic board/interposer having an opening defined therethrough; and
a solder resist material layer disposed on the microelectronic board/interposer having an opening defined therethrough that exposes at least a portion of the joint pad;
wherein the joint pad opening and the solder resist material layer opening define a gap between the joint pad and the solder resist material layer extending adjacent a periphery of solder resist material layer opening and along about 50% and 75% of the solder resist material layer opening periphery.
a microelectronic package including a microelectronic device and having at least one joint pad; and
an interconnect extending between the at least one attachment structure and the microelectronic package joint pad.

4. The microelectronic structure of claim 3, wherein an average width of the attachment structure gap is between about 5% and 20% of an average diameter of the solder resist material layer opening.

5. The microelectronic structure of claim 3, wherein the interconnect does not contact the solder resist material layer.

6. The microelectronic structure of claim 3, wherein the interconnect comprises a solder material.

7. The microelectronic structure of claim 3, wherein the attachment structure gap includes a midpoint vector oriented perpendicular to an edge of the microelectronic device nearest the attachment structure gap.

8. The microelectronic structure of claim 7, wherein the attachment structure gap is positioned substantially opposite the microelectronic device edge.

9. The microelectronic structure of claim 3, wherein the attachment structure gap includes a midpoint vector oriented perpendicular to an edge of the microelectronic device nearest the attachment structure gap, such that the attachment structure gap is positioned substantially opposite the microelectronic device edge, and wherein the interconnect does not contact the solder resist material layer.

10. The microelectronic structure of claim 3, wherein an average width of the attachment structure gap is between about 5% and 20% of an average diameter of the solder resist material layer opening, wherein the attachment structure gap includes a midpoint vector oriented perpendicular to an edge of the microelectronic device nearest the attachment structure gap, such that the attachment structure gap is positioned substantially opposite the microelectronic device edge, and wherein the interconnect comprises a solder material which does not contact the solder resist material layer.

11. The microelectronic structure of claim 3, wherein the attachment structure gap includes a midpoint vector oriented toward a center point of the microelectronic device.

12. The microelectronic structure of claim 11, wherein the attachment structure gap is positioned substantially opposite the microelectronic device center point.

13. The microelectronic structure of claim 3, wherein the attachment structure gap includes a midpoint vector oriented toward a center point of the microelectronic device, such that the attachment structure gap is positioned substantially opposite the microelectronic device center point, and wherein the interconnect does not contact the solder resist material layer.

14. The microelectronic structure of claim 3, wherein an average width of the attachment structure gap is between about 5% and 20% of an average diameter of the solder resist material layer opening, wherein the attachment structure gap includes a midpoint vector oriented toward a center point of the microelectronic device, such that the attachment structure gap is positioned substantially opposite the microelectronic device center point, and wherein the interconnect comprises a solder material which does not contact the solder resist material layer.

15. An electronic system, comprising:
a housing;
a microelectronic board/interposer disposed within the housing;
at least one attachment structure including:
a joint pad disposed on the microelectronic board/interposer having an opening defined therethrough; and
a solder resist material layer disposed on the microelectronic board/interposer having an opening defined therethrough that exposes at least a portion of the joint pad;
wherein the joint pad opening and the solder resist material layer opening define a gap between the joint pad and the solder resist material layer extending adjacent a periphery of solder resist material layer opening and along about 50% to 75% of the solder resist material layer opening periphery.
a microelectronic package including a microelectronic device and having at least one joint pad; and
an interconnect extending between the at least one attachment structure and the microelectronic package joint pad.

16. The electronic system of claim 15, wherein an average width of the attachment structure gap is between about 5% to 20% of an average diameter of the solder resist material layer opening.

17. The electronic system of claim 15, wherein the interconnect does not contact the solder resist material layer.

18. The electronic system of claim 15, wherein the interconnect comprises a solder material.

19. The electronic system of claim 15, wherein the attachment structure gap includes a midpoint vector oriented perpendicular to an edge of the microelectronic device nearest the attachment structure gap.

20. The electronic system of claim 19, wherein the attachment structure gap is positioned substantially opposite the microelectronic device edge.

21. The electronic system of claim 15, wherein an average width of the attachment structure gap is between about 5% and 20% of an average diameter of the solder resist material layer opening, wherein the attachment structure gap includes a midpoint vector oriented perpendicular to an edge of the microelectronic device nearest the attachment structure gap such that the attachment structure gap is positioned substantially opposite the microelectronic device edge, and wherein the interconnect comprises a solder material which does not contact the solder resist material layer.

22. The electronic system of claim 15, wherein the attachment structure gap includes a midpoint vector oriented toward a center point of the microelectronic device.

23. The electronic system of claim 22, wherein the attachment structure gap is positioned substantially opposite the microelectronic device center point.

24. The electronic system of claim 15, wherein an average width of the attachment structure gap is between about 5% and 20% of an average diameter of the solder resist material layer opening, wherein the attachment structure gap includes a midpoint vector oriented toward a center point of the microelectronic device such that the attachment structure gap is positioned substantially opposite the microelectronic device center point, and wherein the interconnect comprises a solder material which does not contact the solder resist material layer.
